(19) United States
(12) Patent Application Publication
(10) Pub. No.: US 2024/0347335 A1
(43) Pub. Date: Oct. 17, 2024

(54) METHOD FOR DEPOSITING AMORPHOUS CARBON FILM

(71) Applicant: TES Co., Ltd, Yongin-si (KR)

(72) Inventors: Kwang-Ki Kim, Yongin-si (KR); Nam-Seo Kim, Yongin-si (KR)

(73) Assignee: TES Co., Ltd, Yongin-si (KR)

(21) Appl. No.: 18/635,055

(22) Filed: Apr. 15, 2024

(30) Foreign Application Priority Data
Apr. 13, 2023 (KR) 10-2023-0048911

(51) Int. Cl. H01L 21/02; C23C 16/26; C23C 16/505

(52) U.S. Cl. CPC H01L 21/02115; C23C 16/26; C23C 16/505; H01L 21/02205; H01L 21/02274

(57) ABSTRACT

Disclosed are an amorphous carbon film having relatively low compressive stress while also having high selectivity and a method for depositing the same. The method includes (a) loading a substrate into a chamber, and (b) depositing an amorphous carbon film doped with oxygen and nitrogen on the substrate by discharging a precursor containing carbon, a precursor containing oxygen, and a precursor containing nitrogen.

### CROSS-REFERENCE TO RELATED APPLICATION

This application claims priority to Korean Patent Application No. 10-2023-0048911 (filed on Apr. 13, 2023), which is hereby incorporated by reference in its entirety.

### BACKGROUND

The present disclosure relates to a technology of depositing an amorphous carbon film that is mainly used as a hard mask in a semiconductor manufacturing process. More specifically, the present disclosure relates to an amorphous carbon film having relatively low compressive stress while also having high selectivity and a method for depositing the same.

NAND device structures that are recently being applied in a semiconductor manufacturing process include a horizontal NAND structure and a vertical NAND structure. As a finer pattern is required, a lot of research has been done recently on the vertical NAND (VNAND) structure.

To achieve the vertical NAND structure, a hard mask process that requires high selectivity is required. To meet such requirement, an amorphous carbon film (ACL) has been used as a representative hard mask. The amorphous carbon film is deposited as the hard mask on a multi-layer insulating film in which tens to hundreds of layers of silicon oxide and silicon nitride films are alternately stacked in a vertical direction using a plasma enhanced chemical vapor deposition (PECVD) process and then a narrow, long hole that vertically extends through the multi-layer insulating film is defined via an etching process.

Considering the great number of layers of the multi-layer insulating film in the vertical NAND device, selectivity of the amorphous carbon film must be high for the amorphous carbon film to properly function as the hard mask.

Several methods have been proposed to increase the selectivity of the amorphous carbon film. For example, Korean Patent Application Publication No. 10-2017-0093003 (2017 Aug. 14.) discloses a method for depositing an amorphous carbon film having a multi-layer structure in which boron-doped carbon films and boron-undoped carbon films are alternately stacked by repeating depositing a carbon film without dopant implanted using a hydrocarbon precursor and depositing a carbon film implanted with the dopant using the hydrocarbon precursor and a boron precursor.

When the selectivity of the amorphous carbon film increases, compressive stress also tends to increase. However, when the compressive stress increases excessively, a problem may occur in wafer chucking, which may result in a decrease in a device yield.

### SUMMARY

The present disclosure is to provide a method for depositing an amorphous carbon film having relatively low compressive stress while also having high selectivity via a PECVD process control.

Furthermore, the present disclosure is to provide an amorphous carbon film having relatively low compressive stress while also having high selectivity.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

An aspect of the present disclosure provides a method for depositing an amorphous carbon film including (a) loading a substrate into a chamber, and (b) depositing an amorphous carbon film doped with oxygen and nitrogen on the substrate by discharging a precursor containing carbon, a precursor containing oxygen, and a precursor containing nitrogen.

In one implementation, the precursor containing carbon may be a carbon compound in a gaseous state.

In one implementation, the precursor containing oxygen may be oxygen gas. The oxygen gas may be supplied into the chamber at a flow rate in a range from about 80 to about 500 sccm. In one implementation, the precursor containing nitrogen may include nitrogen gas. The nitrogen gas may be supplied into the chamber at a flow rate in a range from about 100 to about 1000 sccm.

In one implementation, the (b) may be performed under conditions of a process pressure in a range from about 3 to about 8 Torr, plasma power in a range from about 1000 to about 3000 W, and a substrate temperature in a range from about 400 to about 650° C.

In one implementation, the precursor containing carbon may be supplied together with Ar or He.

Another aspect of the present disclosure provides an amorphous carbon film having a carbon base doped with oxygen and nitrogen, and having a compressive stress equal to or lower than about 200 MPa and a modulus equal to or higher than about 40 MPa.

In one implementation, the amorphous carbon film may exhibit a Vickers hardness equal to or higher than about 5.0 GPa.

According to the amorphous carbon film deposition method according to the present disclosure, the amorphous carbon film doped with oxygen and nitrogen may be deposited using the precursor containing oxygen and the precursor containing nitrogen along with the precursor containing carbon.

The amorphous carbon film doped with oxygen and nitrogen according to the present disclosure was able to have the low compressive stress while also having the high selectivity. Therefore, the amorphous carbon film doped with oxygen and nitrogen may suppress the wafer chucking defect that may occur because of the excessively high compressive stress.

Furthermore, the amorphous carbon film doped with oxygen and nitrogen according to the present disclosure may have the high modulus while also having the low compressive stress, and thus, may, for example, be used as the hard mask for manufacturing the vertical NAND device without increasing the thickness of the amorphous carbon film.

Effects of the present disclosure are not limited to the above-mentioned effects, and other effects as not mentioned will be clearly understood by those skilled in the art from following descriptions.

### BRIEF DESCRIPTION OF DRAWINGS

FIG. 1 schematically shows an amorphous carbon film deposition method according to the present disclosure.

FIG. 2 schematically shows an example of a PECVD apparatus that may be used for an amorphous carbon film deposition method according to the present disclosure.

FIG. 3 shows stresses and hardnesses of amorphous carbon films deposited according to Present Examples and Comparative Examples.

FIG. 4 shows stresses and moduli of amorphous carbon films deposited according to Present Examples and Comparative Examples.

FIG. 5 shows hardnesses and moduli of amorphous carbon films deposited according to Present Examples and Comparative Examples.

### REFERENCE NUMERALS

1: PECVD apparatus
2: chamber
3: shower head
4: susceptor
5: RF power
6: first electrode
7: RF filter
8: ground line

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In general, the amorphous carbon film refers to a film in which carbon atoms are arranged in an amorphous state, unlike graphite in which the carbon atoms are arranged regularly. The amorphous carbon film has high etching selectivity and high rigidity, making it suitable for use as a hard mask in a semiconductor process, especially a process that requires deep vertical etching.

However, when a thickness of a material to be etched increases, like a multi-layer insulating film of a vertical NAND device, a thickness of the amorphous carbon film also needs to increase for the amorphous carbon film to serve as the hard mask until the end of etching. The increase in the thickness of the amorphous carbon film may cause problems such as decreased productivity and deteriorated critical dimension (CD) characteristics. Therefore, an amorphous carbon film with high modulus along with high selectivity is required, which may be achieved by an amorphous carbon film with compressive stress. However, when the compressive stress is too high, a problem such as poor wafer chucking may occur. Therefore, an amorphous carbon film having relatively low compressive stress while also having high selectivity is needed. As a result of long-term research, the inventors of the present disclosure have found that, when doping oxygen (O₂) and nitrogen (N₂) together while depositing the amorphous carbon film using a plasma enhanced chemical vapor deposition (PECVD) process, the amorphous carbon film having the relatively low compressive stress while also having the high selectivity may be deposited.

This is derived from the fact that dissociated species of oxygen and nitrogen generated via the plasma process may react with hydrogen dissociated from hydrocarbon, for example, C₃H₆ to reduce a hydrogen content, and thus, a rate of carbon film formation with a sp3 structure rather than a sp2 structure may increase.

As a result, even with similar compressive stress, the sp3 structure increases, so that an amorphous carbon film that is relatively harder and has excellent selectivity may be deposited. Likewise, an amorphous carbon film having low compressive stress even with similar selectivity may be deposited.

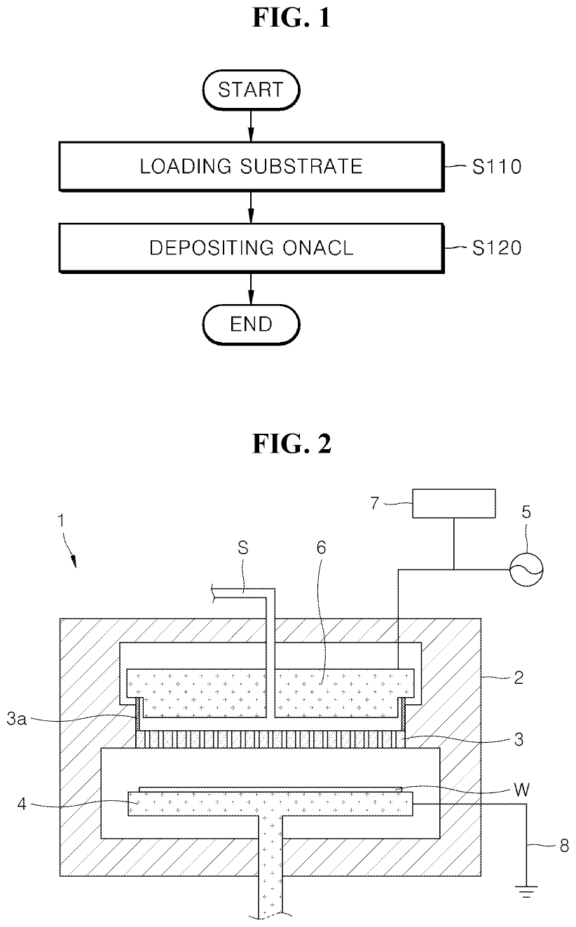

FIG. 1 schematically shows an amorphous carbon film deposition method according to the present disclosure.

Referring to FIG. 1, the shown amorphous carbon film deposition method includes loading a substrate (S110) and depositing an ONACL (Oxygen-doped and Nitrogen-doped Amorphous Carbon Layer) (S120).

The amorphous carbon film deposition method shown in FIG. 1 may use, for example, a PECVD apparatus shown in FIG. 2.

Referring to FIG. 2, the shown PECVD apparatus 1 includes a gas supply line S, a chamber 2, a shower head 3, a susceptor 4, an RF power source 5, and a first electrode 6.

The gas supply line S serves to supply reaction gas, inert gas, and the like from the outside of the chamber 2 into the chamber 2. FIG. 2 shows only one gas supply line S connected to the chamber 2. In this case, a plurality of gas supply lines may be connected to the one gas supply line connected to the chamber 2. As another example, each gas supply line may be connected to the chamber 2.

For example, when a precursor containing carbon is hydrocarbon gas and a precursor containing oxygen is oxygen gas, a possibility of reaction thereof is somewhat high, so that it is preferable that the hydrocarbon gas and the oxygen gas are respectively supplied to separate chambers and then come into contact with each other in the chamber 2. It is more preferable that the hydrocarbon gas and the oxygen gas come into contact with each other at a location between the shower head 3 and the susceptor 4.

Gas supplied into the chamber via the one or the plurality of gas supply lines may be the precursor containing carbon, the precursor containing oxygen, a precursor containing nitrogen, the inert gas, and the like. The precursor containing carbon may be supplied independently into the chamber without carrier gas or may be supplied into the chamber together with the inert gas as the carrier gas. Likewise, the precursor containing oxygen or the precursor containing nitrogen may also be supplied into the chamber independently or together with the inert gas.

In one example, when the precursor containing carbon is in a liquid state, it may be vaporized via a vaporizer and supplied into the chamber.

The inert gas may be supplied into the chamber together with another precursor or may be supplied into the chamber via a separate gas supply line.

The shower head 3 is disposed at an upper side inside the chamber 2 and sprays the gas injected via the gas supply line S into the chamber.

At a lower side inside the chamber 2, the susceptor 4 where a substrate W like a wafer is loaded (supported) is disposed. The susceptor 4 may be equipped with temperature adjust means for heating/cooling the substrate. Furthermore, the susceptor 4 may function as a ground electrode, as in the example shown in FIG. 1. A separate ground line 8 may be disposed to further improve a grounding performance. Although not shown, the susceptor 4 may be constructed as a second electrode (a bias electrode) by connecting a high-frequency power source or a DC power source to the susceptor 4 itself.

The first electrode 6 is electrically connected to the RF power source 5 and is used as an electrode for plasma discharge within the chamber 2. In the example shown in FIG. 1, the shower head 3 is electrically connected 3a to the first electrode 6, so that the first electrode 6 and the shower head 3 function together as a single electrode. Accordingly, RF power generated from the RF power source 5 is applied into the process chamber 2 via the first electrode 6 and the shower head 3. An RF filter 7 serves to remove signal interference occurring around the process chamber 2.

In addition to using the PECVD apparatus illustrated in FIG. 2, the amorphous carbon film deposition method according to the present disclosure may use various known PECVD apparatus.

Going back to FIG. 1, in the loading of the substrate (S110), the substrate W is loaded onto the susceptor 4 within the chamber. Thereafter, the inside of the process chamber 2 is vacuumized using an external vacuum system (not shown).

In the depositing of the ONACL (S120), the precursor containing carbon, the precursor containing oxygen, and the precursor containing nitrogen are discharged to deposit an amorphous carbon film doped with oxygen and nitrogen on the substrate. In other words, while starting to supply the precursor containing carbon, the inert gas, the precursor containing oxygen, and the precursor containing nitrogen, the RF power of approximately 1000 to 3000 W is applied from the RF power source 5 to discharge carbon compound gas between the shower head 3 and the susceptor 4, thereby depositing the amorphous carbon film on the substrate.

The precursor containing carbon, the precursor containing oxygen, and the precursor containing nitrogen may be discharged from the inside of the chamber 2 of the PECVD apparatus shown in FIG. 2. As another example, at least some of the precursor containing carbon, the precursor containing oxygen, and the precursor containing nitrogen may be discharged from a remote plasma system (RPS) outside the chamber and supplied into the chamber.

As the precursor containing carbon, a carbon compound in a liquid state such as methanol (CH₃OH) and a carbon compound in a gaseous state such as gaseous hydrocarbon like acetylene (C₂H₂) or propene (C₃H₆) may be used. Among those, the carbon compound in the liquid state must be accompanied by the separate vaporizer, and the carbon compound in the gaseous state may be more advantageous in depositing the amorphous carbon film with the high selectivity. In the present disclosure, the selectivity is for SiO₂ unless otherwise stated. Therefore, it is more preferable to use the carbon compound in the gaseous state for the precursor containing carbon.

A supply amount of the precursor containing carbon may be set differently depending on the thickness of the amorphous carbon film to be deposited, a temperature of the process chamber, and the like. For example, the precursor containing carbon may be supplied at a flow rate in a range from 500 to 1500 sccm.

Furthermore, the precursor containing carbon may be supplied into the chamber together with the inert gas such as helium gas (He) or argon gas (Ar). Each inert gas may be supplied into the process chamber at a flow rate equal to or lower than about 4000 sccm. For example, argon gas may be supplied into the chamber at a flow rate in a range from 2000 to 4000 sccm and helium gas may be supplied into the chamber at a flow rate in a range from 200 to 1000 sccm, but the present disclosure may not be limited thereto.

In one example, when depositing the amorphous carbon film with the high selectivity using only the carbon compound in the gaseous state, the compressive stress may be excessively increased. In the present disclosure, to solve such problem, the amorphous carbon film doped with oxygen and nitrogen was deposited using the precursor containing oxygen and the precursor containing nitrogen together with the precursor containing carbon.

The precursor containing oxygen may be gas containing oxygen such as oxygen gas (O₂) or ozone gas (O₃). Among those, it is more preferable to use oxygen gas. The precursor containing nitrogen may be gas containing nitrogen such as nitrogen gas (N₂) or ammonia gas (NH₃). Among those, it is more preferable to use nitrogen gas.

In one example, a precursor containing both oxygen and nitrogen such as nitrogen oxides including NO, NO₂, N₂O, and the like may be considered. However, when the nitrogen oxide is used, a deposition rate of the amorphous carbon film may be excessively low compared to a case in which oxygen gas and nitrogen gas are used separately.

The precursor containing oxygen may be supplied into the chamber at a flow rate in a range from about 80 to about 500 sccm. The precursor containing nitrogen may be supplied into the chamber at a flow rate in a range from about 100 to about 1000 sccm. When the flow rate of the precursor containing oxygen or the precursor containing nitrogen is too low, it may be difficult to simultaneously achieve the high selectivity and the low compressive stress that are aimed because of insufficient doping of oxygen and/or nitrogen. Conversely, when the flow rate of the precursor containing oxygen or the precursor containing nitrogen is too high, properties such as modulus of the amorphous carbon film may be reduced without further effect.

The depositing of the ONACL (S120) may be performed under normal amorphous carbon film deposition conditions. For example, the depositing of the ONACL (S120) may be performed under conditions of a process pressure in a range from about 3 to about 8 Torr, a plasma power in a range from about 1000 to about 3000 W, and a substrate temperature in a range from about 400 to about 650° C. That is, in the present disclosure, the amorphous carbon film is deposited via the normal PECVD process, but the precursor containing oxygen and the precursor containing nitrogen are supplied into the chamber together with the precursor containing carbon.

According to the amorphous carbon film deposition method according to the present disclosure as described above, the amorphous carbon film doped with oxygen and nitrogen may be deposited using the precursor containing oxygen and the precursor containing nitrogen along with the precursor containing carbon.

In the amorphous carbon film according to the present disclosure, oxygen and nitrogen are doped into a carbon base. Because oxygen and nitrogen are doped, the amorphous carbon film according to the present disclosure may have a compressive stress equal to or lower than about 200 MPa and a modulus equal to or higher than about 40 MPa. Amorphous carbon films deposited via a high-temperature PECVD process using gaseous hydrocarbon may also have a modulus equal to or higher than 40 MPa. In this case, the amorphous carbon films mostly have a high compressive stress equal to or higher than 200 MPa. In contrast, the amorphous carbon film according to the present disclosure has the modulus equal to or higher than 40 MPa, but unusually has the relatively low compressive stress equal to or lower than 200 MPa. This may also be identified with FIG. 4.

Accordingly, the amorphous carbon film doped with oxygen and nitrogen according to the present disclosure may have the high modulus while having the low compressive stress, and thus, may be, for example, used as the hard mask for manufacturing the vertical NAND device without increasing the thickness of the amorphous carbon film.

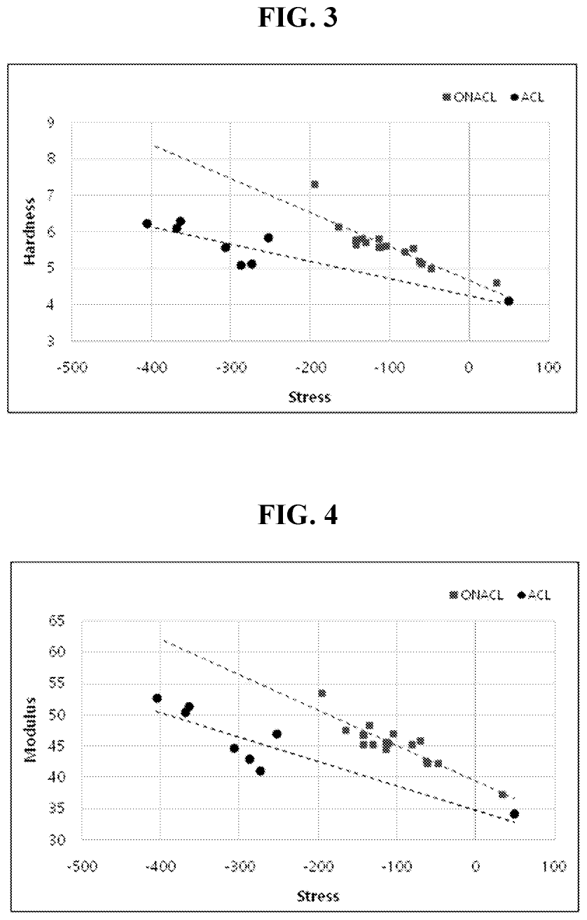

Furthermore, the amorphous carbon film according to the present disclosure may exhibit a Vickers hardness equal to or higher than about 5.0 GPa. Likewise, the amorphous carbon film according to the present disclosure has the relatively low compressive stress equal to or lower than about 200 MPa while exhibiting a high hardness equal to or higher than about 5.0 GPa. This may also be identified with FIG. 3.

### Present Examples

Hereinafter, a composition and an operation of the present disclosure will be described in more detail with preferred present examples of the present disclosure. However, these are presented as desirable examples of the present disclosure and are not able to be interpreted as limiting the present disclosure in any way.

Information not described herein may be technically inferred by anyone skilled in this technical field, so that a description thereof will be omitted.

Amorphous carbon films according to Present Examples 1 to 14 were deposited under conditions listed in Table 1 and amorphous carbon films according to Comparative Examples 1 to 8 were deposited under conditions listed in Table 2.

TABLE 1

| Precursor containing carbon | C₃H₆ | |
|---|---|---|
| Ar flow rate | 2000~4000 | sccm |
| He flow rate | 200~1000 | sccm |
| O₂ flow rate | 80~500 | sccm |
| N₂ flow rate | 100~1000 | sccm |
| Chamber pressure | 3~8 | Torr |
| RF power | 1000~3000 | W |
| Substrate temperature | 400~650° | C. |

TABLE 2

| Precursor containing carbon | C₃H₆ | |
|---|---|---|
| Ar flow rate | 2000~4000 | sccm |
| He flow rate | 200~1000 | sccm |
| O₂ flow rate | 0 | sccm |
| N₂ flow rate | 0 | sccm |
| Chamber pressure | 3~8 | Torr |
| RF power | 1000~3000 | W |
| Substrate temperature | 400~650° | C. |

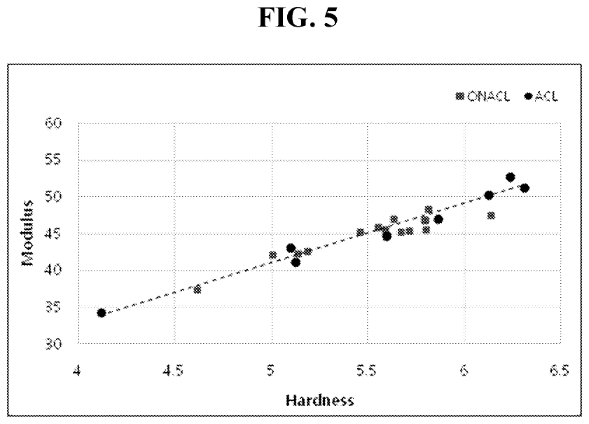

FIG. 3 shows stresses and hardnesses of amorphous carbon films (ONACL) deposited according to Present Examples and amorphous carbon films (ACL) deposited according to Comparative Examples. FIG. 4 shows stresses and moduli of amorphous carbon films deposited according to Present Examples and Comparative Examples. FIG. 5 shows hardnesses and moduli of amorphous carbon films deposited according to Present Examples and Comparative Examples. In FIGS. 3 to 5, the amorphous carbon films deposited according to Present Example are indicated by ONACL and the amorphous carbon films deposited according to Comparative Examples are indicated by ACL.

Referring to FIG. 3, it may be seen that the amorphous carbon films deposited according to Present Examples and the amorphous carbon films deposited according to Comparative Examples generally exhibit Vickers hardnesses equal to or higher than 5.0 GPa, except for exceptional cases. In particular, it may be seen that the amorphous carbon films deposited according to Present Examples have the Vickers hardnesses similar to those of the amorphous carbon films deposited according to Comparative Examples, but the amorphous carbon films deposited according to Present Examples have relatively low compressive stresses compared to the amorphous carbon films deposited according to Comparative Examples having relatively high compressive stresses.

Referring to FIG. 4, it may be seen that the amorphous carbon films deposited according to Present Examples and the amorphous carbon films deposited according to Comparative Examples generally exhibit moduli equal to or higher than 40 MPa, except for exceptional cases. In particular, it may be seen that the amorphous carbon films deposited according to Present Examples have moduli similar to those of the amorphous carbon films deposited according to Comparative Examples, but the amorphous carbon films deposited according to Present Examples have relatively low compressive stresses compared to the amorphous carbon films deposited according to Comparative Examples having relatively high compressive stresses.

In one example, referring to FIG. 5, it may be seen that the moduli also tend to increase as the hardnesses increase in the amorphous carbon films deposited according to Present Examples and the amorphous carbon films deposited according to Comparative Examples.

Table 3 shows characteristics of the amorphous carbon films prepared according to Comparative Examples 9 and 10 and Present Examples 15 and 16. In Comparative Examples 9 and 10 and Present Examples 15 and 16, the same process conditions were applied except for the conditions shown in Table 3.

TABLE 3

| | Comparative | Comparative | Present | Present |
|---|---|---|---|---|
| | Example 9 | Example 10 | Example 15 | Example 16 |
| O₂ flow rate | 0 | 0 | 200 | 400 |
| N₂ flow rate | 0 | 0 | 800 | 600 |
| Deposition rate | 60 | 31 | 55 | 53 |
| (Å/s) | | | | |
| Extinction | 0.555 | — | 0.767 | 0.770 |
| coefficient | | | | |
| Film stress | 48.8 | −244 | −190 | −195 |
| (MPa) | | | | |
| Vickers | 4.1 | — | 7.7 | 7.3 |
| hardness (GPa) | | | | |
| Modulus (MPa) | 34.3 | — | 55.5 | 53.5 |
| Selectivity (%) | 100 | 121 | 120 | 124 |

In Table 3, the selectivity refers to selectivity for SiO₂. Selectivity of the amorphous carbon film according to Comparative Example 9 is set as 100% and relative selectivity of the remaining amorphous carbon films are shown.

Referring to Table 3, it may be seen that the amorphous carbon film according to Comparative Example 10, which has a very low deposition rate without O₂ and N₂ supply, shows higher selectivity than the amorphous carbon film according to Comparative Example 9, but the compressive stress also greatly increases.

On the other hand, it may be seen that the amorphous carbon films according to Present Examples 15 and 16 in which O₂ and N₂ were supplied together with C₃H₆ show high selectivity similar to that of the amorphous carbon film according to Comparative Example 10, but the compressive stresses are relatively low and the deposition rates are also higher than that of Comparative Example 10.

Furthermore, the amorphous carbon films according to Present Examples 15 and 16 show relatively high extinction coefficients compared to that of Comparative Example 9. The higher the extinction coefficient, the closer the amorphous carbon film becomes to black, showing that a density of the film has increased.

Therefore, judging from the results in Table 3, using the precursor containing oxygen and the precursor containing nitrogen along with hydrocarbon in the gaseous state may be considered more advantageous in depositing the amorphous carbon film with the high selectivity and low compressive strength.

Although the embodiments of the present disclosure have been described in more detail with reference to the accompanying drawings, the present disclosure is not necessarily limited to the embodiments, and may be modified in a various manner in the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A method for depositing an amorphous carbon film, the method comprising:
(a) loading a substrate into a chamber; and
(b) depositing an amorphous carbon film doped with oxygen and nitrogen on the substrate by discharging a precursor containing carbon, a precursor containing oxygen, and a precursor containing nitrogen.

2. The method of claim 1, wherein the precursor containing carbon is a carbon compound in a gaseous state.

3. The method of claim 1, wherein the precursor containing oxygen is oxygen gas.

4. The method of claim 3, wherein the precursor containing oxygen is supplied into the chamber at a flow rate in a range from about 80 to about 500 sccm.

5. The method of claim 1, wherein the precursor containing nitrogen is nitrogen gas.

6. The method of claim 5, wherein the precursor containing nitrogen is supplied into the chamber at a flow rate in a range from about 100 to about 1000 sccm.

7. The method of claim 1, wherein the (b) is performed under conditions of a process pressure in a range from about 3 to about 8 Torr, plasma power in a range from about 1000 to about 3000 W, and a substrate temperature in a range from about 400 to about 650° C.
